(19) United States
(12) Patent Application Publication
(10) Pub. No.: US 2007/0094557 A1
(43) Pub. Date: Apr. 26, 2007

(54) Semiconductor integrated circuit tester

(76) Inventor: Kenneth L. Skala, Fremont, CA (US)

Correspondence Address: SMITH-HILL AND BEDELL, P.C., 16100 NW CORNELL ROAD, SUITE 220, BEAVERTON, OR, 97006, US

(21) Appl. No.: 11/256,321

(22) Filed: Oct. 21, 2005

(51) Int. Cl. G01R 31/28

(52) U.S. Cl. 714/724

(57) ABSTRACT

A semiconductor integrated circuit tester includes a host computer having a parallel data bus segment, a test head including at least one instrument having a parallel data bus segment, a first network bridge interfacing the data bus segment of the host computer to a switched serial network, and a second network bridge interfacing the data bus segment of the instrument to the switched serial network.

### BACKGROUND OF THE INVENTION

This invention relates to a semiconductor integrated circuit tester.

A general purpose semiconductor integrated circuit tester comprises a host computer and external peripherals that are connected to the host computer and are adapted to the purpose of testing semiconductor integrated circuit devices. The external peripherals include pin electronics cards that are mounted in a test head and are connected to the device under test (DUT) by a load board (or DUT board) that serves as a physical and electrical interface between the pin electronics cards and the device under test. In the case that the tester is to be used to test packaged devices, the load board has a DUT socket and a device handler places units of the DUT in the device socket for testing and removes the units from the device socket after testing. The test head is supported by a manipulator for positioning the test head for docking to the device handler.

Each pin electronics card implements several tester channels, which perform test activities at respective pins of the DUT based on test data received from the host computer. The pin electronics cards may be of several different types, such as mixed signal cards and logic test cards. Although each card is relatively compact, the test head may include numerous cards and may accordingly be quite bulky.

In order to carry out a typical test, test data defining the test is delivered from the host computer to the pin electronics cards and the pin electronics cards supply stimulus signals to the DUT and acquire response signals from the DUT in accordance with the test defined by the test data. The pin electronics cards return the response data to the host computer and the host computer interprets the response data and reports the result of the test accordingly.

In current general purpose testers, the host computer communicates with the pin electronics cards over one or more parallel buses. In order to deliver the test data, the host computer may place address and test data words on a parallel bus and assert suitable control signals, and the pin electronics cards respond to the control signals by reading the test data from the bus and writing the test data to the memory location specified by the address. Thus, the host computer controls the procedure by which the test data is supplied to the pin electronics cards, and the pin electronics cards respond to instructions provided by the host computer.

In the case of a complex device, such as a device having several hundred pins, it might take several minutes to deliver the large quantity of data required to define a test from the host computer to the pin electronics cards.

Until recently, the focus of semiconductor integrated circuit testers has been on providing the capability to test ever more complex devices with ever increasing pin count, such as the successive generations of microprocessors. However, there is also a need for testing the smaller and simpler devices, with lower pin counts, e.g. fewer than 100 pins, that are used in many consumer products such as MP3 players, digital cameras and GPS receivers. For every microprocessor that is tested, it may be necessary to test many more smaller and less complex devices. The volume of test data required to test a relatively simple device might be as small as about 64 KB.

A tester suitable for testing a single relatively small and simple electronic device may require much less computing power than the conventional general purpose tester. In fact, a typical personal computer such as one based on a microprocessor operating at 2.4 GHz has sufficient computing power for testing a single relatively small and simple electronic device in an acceptably short time.

A typical personal computer includes a central processing unit (CPU) that communicates with various integrated peripherals, such as an internal hard disk drive, a graphics adapter and a USB adapter, and also communicates with external peripherals, such as printers, over a PCI (Peripheral Component Interconnect) parallel bus and adapter cards that are connected to the PCI bus by plugging the cards into PCI slots. The PCI standard specifies that the PCI bus is 32 or 64 bits wide and operates at a frequency of 33 MHz or 66 MHz. In many inexpensive personal computers, the PCI bus is 32 bits wide, in which case the data transport rate is 132 MB/s or 264 MB/s, depending on bus frequency. Clearly it would take very little time to transfer 64 KB of data from the CPU to a peripheral device over a bus having a transfer rate of 132 MB/s. Accordingly, a person of ordinary skill in the art might consider that the most logical way of adapting an inexpensive personal computer to use in a special purpose tester, as described above, would be employ an architecture similar to that of the conventional general purpose tester, with a parallel bus for delivering the test data from the CPU to the pin electronics cards. Potentially, the most simple solution would be to extend the PCI bus from the computer to the test head. However, a person skilled in the art would quickly realize that it would not be possible to extend the PCI bus over a sufficient distance to serve pin electronics cards in a tester without dramatically degrading the data transport rate. In fact, the data transport rate may fall as low as 2 MB/s if the PCI bus were extended as suggested above. Accordingly the idea of testing simple devices using a special purpose tester based on an inexpensive personal computer is not as promising as it might at first appear.

The barrier to using a special purpose tester based on an inexpensive personal computer is even greater than might at first appear, because the growth in demand for consumer electronic devices has made it desirable, if not essential, to employ multi-site testing for testing such devices. In multi-site testing, the load board has multiple DUT sockets for receiving respective units of-the DUT so that multiple devices can be tested simultaneously. In the case of the classic parallel data bus implementation described above, if the test head were configured for testing four units simultaneously, the data transport rate per DUT would fall from 2 MB/s to 0.5 MB/s and the data processing power per DUT would fall from 2.4 GHz to 600 MHz. Although this reduction in processing power and data transport rate per DUT would not affect all functions of the tester, it nevertheless effectively precludes multi-site testing from meeting some of the expectations for this technology.

### SUMMARY OF THE INVENTION

According to the present invention there is provided a tester comprising a host computer having a parallel data bus segment, a test head including at least one instrument having a parallel data bus segment, a first network bridge interfacing the data bus segment of the host computer to a switched serial network, and a second network bridge interfacing the data bus segment of the instrument to the switched serial network.

### BRIEF DESCRIPTION OF THE DRAWINGS

For a better understanding of the invention, and to show how the same may be carried into effect, reference will now be made, by way of example, to the accompanying drawings, in which

FIG. 1 is a simplified block diagram of a tester embodying the present invention,

FIG. 2 is a more detailed, but nevertheless highly schematic, block diagram of one cassette of the tester shown in FIG. 1, and

FIG. 3 is a simplified block diagram of an instrument that may be used in the tester shown in FIG. 1.

### DETAILED DESCRIPTION

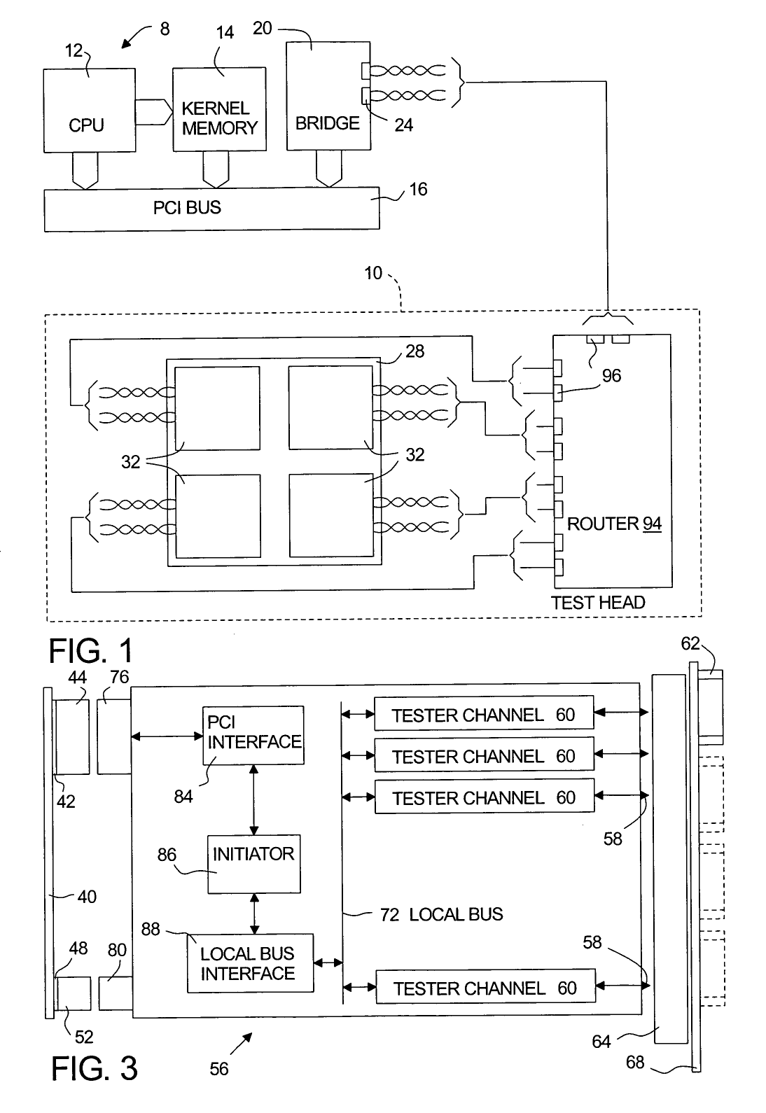

The tester illustrated in FIGS. 1-3 comprises a general purpose personal computer 8 and a test head 10. The computer 8 includes a CPU 12 that communicates with kernel memory 14 and a CompactPCI bus 16. (CompactPCI is functionally similar to standard PCI but uses different packaging and employs plugs and sockets for interconnection, rather than edge connectors and slots. Unless the context indicates otherwise, subsequent references in this Detailed Description to PCI relate to CompactPCI rather than standard PCI.) The PCI bus is 32 bits wide and several PCI sockets are distributed along the bus for receiving PCI plugs. One socket of the PCI bus contains a PCI bridge card 20 that interfaces the parallel PCI bus to a switched serial network environment. At the switched serial network side of the interface, the bridge card 20 has two RJ45 jacks 24 for receiving conventional RJ45 plugs.

The test head 10 is mounted to a manipulator (not shown) for positioning the test head relative to a device handler (not shown). The test head includes a test head chassis 28 that typically defines four compartments for receiving up to four instrument cassettes 32, although it will be understood that the test head chassis may be designed to accommodate fewer than four cassettes or more than four cassettes. Each cassette comprises a cassette chassis and up to ten test instruments 36 installed in the cassette chassis.

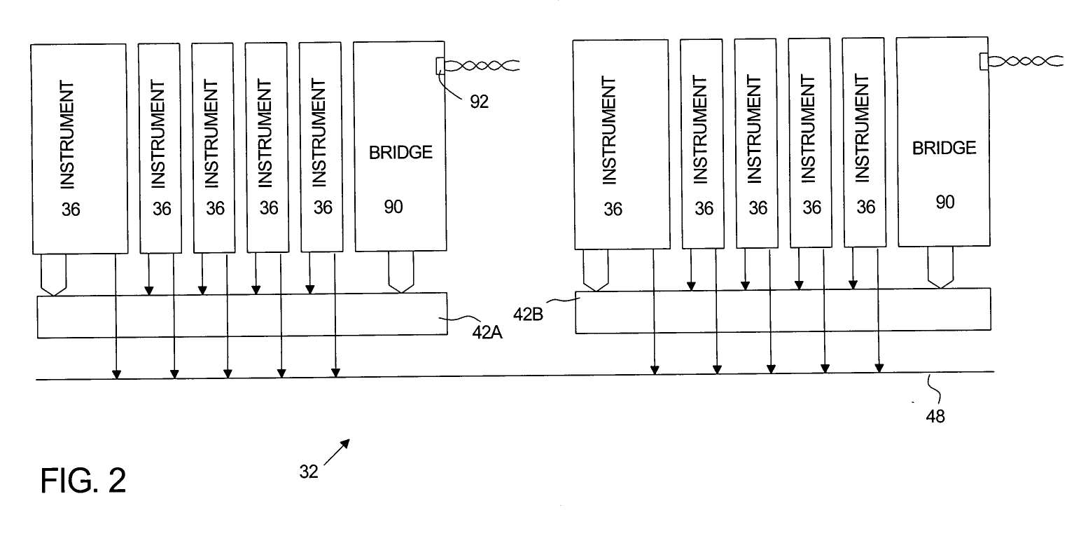

Referring to FIGS. 2 and 3, a typical cassette has a backplane 40 on which are provided two 32-bit PCI bus segments 42A and 42B. The two PCI bus segments are aligned with each other. Each PCI bus segment is provided with six PCI sockets 44. The backplane also supports a DC power rail 48 provided with ten power connectors 52.

Referring to FIG. 3, each test instrument is built on a printed circuit board 56 and implements several (as many as 96) tester channels 60. Generally the tester channels of a given instrument are all functionally equivalent. For example, the channels of a given instrument might implement logic testing functions, in which case each channel is designed to force a corresponding pin of the DUT to a desired potential or compare the potential at that pin to a threshold level. Tester channel terminals 58 at one edge of the board 56 are connected to respective pins of a DUT socket 62 through an interface structure 64 and a load board 68. Test data is supplied to and from the tester channels 60 over a local bus 72. In the event that the test head chassis accommodates multiple cassettes, the interface structure may include portions that are associated with the respective cassettes and portions that are shared among the several cassettes.

Each instrument board 56 is provided at the edge opposite the tester channel terminals 58 with a PCI plug 76 that is complementary to the sockets 44. Each board 56 is also provided with a power connector 80 that is complementary to the connectors 52.

The PCI plug 76 and the local bus 72 communicate by way of a PCI interface 84, a PCI initiator 86 and a local bus interface 88.

When a test instrument 36 is installed in the cassette chassis, the PCI plug 76 engages one of the PCI sockets 42 and the power connector 86 engages the corresponding power connector 52. When all ten instruments are installed, five of the sockets of each PCI bus segment 42 receive respective plugs 76 of five instruments 36. The sixth PCI socket 44 of each bus segment receives a plug of a PCI bridge card 90 having two network connection jacks 92.

The test head also contains a high speed serial network router 94 having ten network ports connected to respective RJ45 jacks 96. Eight ports are used for internal communication within the test head and the remaining two ports are used for communication with the host computer. Eight lengths of conventional serial data cable, such as standard Category 5 or Category 6 network cable, connectorized with RJ45 plugs, are plugged at one end into the respective RJ45 jacks 92 of the bridge cards 90 and at the opposite ends into respective jacks 96 of the data router. Two more lengths of serial data cable are each plugged at one end into the jacks 24 of the bridge card 20 and at the other end into one of the remaining jacks 96 of the router.

In preparing to carry out a test, the CPU publishes the test data in the kernel memory 14 of the computer, thereby making the data available to the PCI bus 16, and sends a signal over the PCI bus 16 and the switched serial network to the test instruments announcing the availability of the test data. This signal is received by the I/O accelerator (PCI initiator) in each test instrument, and the I/O accelerator in each test instrument issues a signal requesting that a streaming connection be established with the host computer and that the test data be supplied by the streaming connection.

Since all instruments request the test data but there is only one router in the data path, the router can only honor one request at a time for a streaming connection. The requests are honored in accordance with a predetermined rule, such as first come, first served. The router passes the request for the test data to the host computer, and the computer responds by streaming the test data from the kernel memory to the requesting instrument. During the streaming connection, the requesting instrument takes control of the network until all the data has been streamed to the requesting instrument.

It will be understood that the kernel memory 14 places the test data in parallel form on the PCI bus 16, the bridge 20 reads the parallel test data from the PCI bus, packetizes the test data and transmits it to the router over the serial data cable, the data router receives the packets of test data and directs them to the requesting instrument, the bridge associated with the requesting instrument receives the data packets and converts the test data back to parallel form and places the test data on the bus segment 42, and the PCI interface, initiator and local bus interface of the requesting instrument receive the parallel test data and deliver it to the tester channels of the requesting instrument over the local bus 72.

Another instrument may then sense that the network is available and request the test data, and the process is repeated. In this manner, the data is transferred to each of the requesting instruments in turn. Although the test data is streamed through the router multiple times, the time taken to transfer the data to all the instruments is nevertheless shorter than if the conventional architecture had been employed, by extending the parallel bus to the instruments.

A switched serial network having the configuration described above may be constructed using conventional commercially available components so that it is able to transfer data at a rate as high as 250 MB/s. Therefore, the data transfer capacity of the switched serial network does not limit the speed at which test data is transferred from the host computer to the instruments.

In the case of single site testing, as described above, the data transport rate per DUT is limited by the data transport rate of the PCI bus and is therefore 132 MB/s. If the tester were used for multi-site testing, by providing additional DUT sockets 62 on the load board as indicated in dashed lines, the data transport rate per DUT would be 132/N MB/s, where N is the total number of sockets.

In a modification of the tester described above, the PCI bus 16 of the host computer and the PCI bus segments 42 of the test instruments are 64 bits wide. The maximum data transport rate over the PCI bus segments is then 264 MB/s, which matches quite well the data transport rate over the switched serial network and avoids the PCI bus segments being the limiting factor on the data transport rate.

A typical personal computer suitable for use as the host computer in the tester described above might be classed as a server computer and have a processor that operates at 3.2 GHz. In a single site tester, as described, the data processing power per DUT would then be 3.2 GHz. If the tester were used for multi-site testing, by providing additional DUT sockets 62 on the load board as mentioned above, the data processing power per DUT would be 3.2/N GHz where N is the total number of sockets. Depending on the nature of the test, it might be desirable to have more processing power available. In another modification of the tester described above, the host computer 8 is employed as a primary computer and one or more secondary computers are also provided. The secondary computers are similar in configuration to the host computer 8, and are connected to the router in similar fashion to the host computer, but the host computer controls the operation of the secondary computers using commands and messages passed over the switched serial network.

It will be appreciated that the invention is not restricted to the particular embodiment that has been described, and that variations may be made therein without departing from the scope of the invention as defined in the appended claims and equivalents thereof. For example, although the embodiment described with reference to FIGS. 1-3 employs a router for passing packets from a source port to a destination port, it another embodiment a switch may be used instead. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. If the word “comprises” or “includes,” or a derivative of either of these words is used in this specification, including the claims, it is used in an inclusive, not exclusive or exhaustive, sense. Thus, for example, a statement that a component comprises first and second elements is not intended to exclude the possibility of the component including one or more additional elements.

1. A tester comprising:
a host computer having a parallel data bus segment,
a test head including at least one instrument having a parallel data bus segment,
a first network bridge interfacing the data bus segment of the host computer to a switched serial network, and
a second network bridge interfacing the data bus segment of the instrument to the switched serial network.

2. A tester according to claim 1, wherein the switched serial network includes a packet switch located in the test head.

3. A tester according to claim 1, wherein the test head comprises a test head chassis, the tester comprises at least one cassette mounted in the test head chassis, and the instrument is mounted in the cassette.

4. A tester according to claim 3, wherein the tester comprises a plurality of instruments mounted in the cassette, the second network bridge is installed in the cassette, the cassette comprises a parallel data bus segment communicating with the second network bridge, each of the plurality of instruments includes a parallel data bus segment, and the data bus segment of the cassette communicates with the data bus segments of the instruments respectively.

5. A tester according to claim 1, wherein the test head comprises a test head chassis, the tester comprises a plurality of cassettes mounted in the test head chassis, the tester comprises a plurality of instruments, and multiple instruments are mounted in each cassette.

6. A tester according to claim 5, comprising a plurality of second network bridges installed in the cassettes respectively, and wherein each cassette comprises a parallel data bus segment communicating with the second network bridge installed in that cassette, each of the multiple instruments mounted in that cassette includes a parallel data bus segment, and the data bus segment of the cassette communicates with the data bus segments of the instruments respectively.

7. A tester according to claim 1, comprising a router located in the test head, and wherein the serial network connects each of the second network bridges to the router.
